(19) United States
(12) Patent Application Publication
(10) Pub. No.: US 2011/0096470 A1
(43) Pub. Date: Apr. 28, 2011

(54) Systems, devices, and methods for distributing electrical energy

(76) Inventors: Joseph Scott Dixon, Suwanee, GA (US); Jeffrey K. Hudgins, JR., Gainesville, GA (US)

(21) Appl. No.: 11/444,610

(22) Filed: Jun. 1, 2006

(51) Int. Cl. H02B 1/04; H05K 13/00; H02B 1/20

(52) U.S. Cl. 361/636; 29/592.1; 361/637

(57) ABSTRACT

Certain exemplary embodiments comprise a basepan assembly for an electrical panel. The basepan assembly can comprise an interconnectable plurality of pieces. In certain exemplary embodiments, a first piece from the plurality of pieces can comprise an inserter. In certain exemplary embodiments, a first piece from the plurality of pieces can comprise a receiver adapted to slidably receive an inserter of a second piece from the plurality of pieces.

### BACKGROUND

United States Patent Publication No. 20040145837 (Davis), which is incorporated by reference herein in its entirety, allegedly recites that “[t] here is provided a method and a basepan assembly for a panel board. The basepan assembly comprises a basepan having a bottom portion and at least one sidewall. A first bus bar is mounted in the bottom portion of the basepan. A second bus bar is mounted to its side proximate the side wall of the basepan. The side wall can include fasteners to couple the second bus bar to the side wall.” See Abstract.

U.S. Pat. No. 6,266,232 (Rose '232), which is incorporated by reference herein in its entirety, allegedly recites an “electric load center having a basepan having a surface with a modular extension mounting foot extending from a lower end wall of a circuit breaker support rail for receiving a modular extension basepan, the modular extension mounting foot having a slot for receiving a flexible snap hook of the modular extension basepan to secure the modular extension basepan to the basepan.” See Abstract.

U.S. Pat. No. 5,969,937 (Rose '937), which is incorporated by reference herein in its entirety, allegedly recites an “electric load center having a basepan having a surface with a modular extension mounting foot extending from a lower end wall of a circuit breaker support rail for receiving a modular extension basepan, the mounting foot having a trapezoidal shaped slot for engagement by a correspondingly shaped ramp of the modular extension basepan, the modular extension mounting foot further having a slot for receiving a flexible snap hook of the modular extension basepan to secure the modular extension basepan to the basepan.” See Abstract.

### SUMMARY

Certain exemplary embodiments comprise a basepan assembly for an electrical panel. The basepan assembly can comprise an interconnectable plurality of pieces. In certain exemplary embodiments, a first piece from the plurality of pieces can comprise an inserter. In certain exemplary embodiments, a first piece from the plurality of pieces can comprise a receiver adapted to slidably receive an inserter of a second piece from the plurality of pieces.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1 is a block diagram of an exemplary embodiment of a system 1000;

FIG. 2 is a perspective view of an exemplary embodiment of a basepan system 2000;

FIG. 3 is a plan view of an exemplary embodiment of a system 3000;

FIG. 4 is a side view of an exemplary embodiment of a system 4000;

FIG. 5 is an end view of an exemplary embodiment of a system 5000;

FIG. 6 is a perspective view of an exemplary embodiment of a system 6000; and

FIG. 7 is a flowchart of an exemplary embodiment of a method 7000.

### DEFINITIONS

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a—at least one.
activity—an action, act, step, and/or process or portion thereof.
adapted to—configured to and/or made suitable or fit to facilitate a specific use or situation.
adapter—a device used to effect operative compatibility between different parts of one or more pieces of an apparatus or system.
align—to adjust to produce a proper relationship or orientation.
apparatus—an appliance or device for a particular purpose.
assembly—a plurality of coupled components.
associated with—related to.
at least—at a minimum.
attach—to fasten, secure, couple, and/or join.
attachable—capable of being fastened, secured, coupled, and/or joined.
away—on a path directed from a predetermined location.
basepan—a system, potentially having an irregular surface, adapted to be installed in an electrical panel, the system adapted to have a bus bar and/or one or more circuit breakers mounted thereon and/or thereto.
beneath—under.
bottom—a lowest part of an object relative to a point of reference, the object in a predetermined orientation relative to the point of reference.
bus bar—a common electrical power terminal to which multiple circuits are electrically coupled through either fuses or circuit breakers.
can—is capable of, in at least some embodiments.
channel—to direct along a path.
circuit breaker—a device adapted to automatically open an alternating current electrical circuit.
comprising—including but not limited to.
conductor—substantially capable of transferring something from a first location to a second location.
configured to—made suitable or fit for a specific use or situation.
connect—to join or fasten together.
corresponding—accompanying.
couple—to join, connect, and/or link together.
coupleable—capable of being joined, connected, and/or linked together.
coupling—linking in some fashion.
define—to establish the outline, form, or structure of
device—a machine, manufacture, and/or collection thereof
direction—a distance independent relationship between two points in space that specifies the position of either with respect to the other; the relationship by which the alignment or orientation of any position with respect to any other position is established.
electrical—pertaining to electricity.
end—an extremity of something that defines a length.
fastener—one (or more) restraint that attaches to, extends through, penetrates, and/or holds something. For example, a fastener can be one (or more) bolt and nut assembly, rivet, weldment, nail, screw, peg, staple, clip, buckle, clasp, clamp, hook and loop assembly, adhesive, and/or plastic push rivet, etc.
from—relating to a location of origin.
heat energy—molecular kinetic energy quantifiable by a temperature.
increase—to become greater or more in size, quantity, number, degree, value, intensity, and/or power, etc.
inserter—adapted to be placed into a recessed part or socket.
install—to connect or set in position and prepare for use.
interconnectable—capable of being mechanically connected together.
level—a relative position on a scale.
load—of or related to an electrical energy consuming entity.
lug—a point of attachment adapted to electrically and/or mechanically couple two electrically conductive components.
main circuit breaker—a circuit breaker that is a member of a set of circuit breakers, no other members in the set having a substantially larger safe electrically conductive capacity.
may—is allowed and/or permitted to, in at least some embodiments.
meter—a device adapted to detect and/or record a measured value.
method—a process, procedure, and/or collection of related activities for accomplishing something.
motion—changing position or place.
mount—to fixedly attach.
move—to change position.
mutually—with respect to each other.
mutually electrically insulate—to substantially preclude a flow of electrons between.
mutually perpendicular axes—three lines extending through a defined point, each line orthogonal to each of the other two lines.
one—a single entity.
operative embodiment—an implementation that is used in one or more manners, and/or for one or more functions, specified herein.
panel—a housing adapted to contain electrical components, such as a circuit interrupter, meter, and/or circuit breaker, adapted to manage electrical energy to an electrical device and/or in a circuit.
parallel—of, relating to, or designating two or more straight coplanar lines that do not intersect.
part—component.
perpendicular—substantially at a right angle with respect to a defined line or defined plane.
plane—a two-dimensional surface.
plurality—the state of being plural and/or more than one.
portion—a definable piece or section.
predetermined—established in advance.
provide—to furnish and/or supply.
receive—to take in, hold, or contain.
receiver—a recessed part or socket adapted to receive a corresponding inserter.
releasably—capable of being freed, in a substantially non-destructive manner, from something that binds, fastens, or holds back.
repeatedly—again and again; repetitively.
restrain—to limit and/or restrict.
retain—to restrain motion in at least one direction.
riser bridge—a side panel substantially perpendicular to a plane defined by a basepan bottom.
route—to direct on a path.
piece—a component adapted to form a greater whole when combined with one or more additional pieces.
sensor—a device or system adapted to detect or perceive automatically.
separation—a defined space between.
serpentine shaped—characterized by an undulating contour.
set—a related plurality.
side—an identifiable portion.
slidably—to be able to open, close, and/or fit together with a sliding motion of a first part relative to a second part.
snapably—to be able to open, close, and/or fit together with a click.
space—a gap.
substantially—to a great extent or degree.
substrate—an underlying layer.
support—to bear the weight of, especially from below.
system—a collection of mechanisms, devices, data, and/or instructions, the collection designed to perform one or more specific functions.
thermal—pertaining to temperature.
thermoplastic—a polymeric substance that can be softened by heat and hardened by cooling in a reversible physical process such as, for example, GE Noryl SEI-X (available from GE Plastics, of Pittsfield, Ma.) and/or Asahi Xyron 540V (available from Asahi Kasei America Inc., of New York, N.Y.), etc.
vent—an opening adapted to channel heat energy.
via—by way of and/or utilizing.
wall—a substantially upright structure serving to enclose an area.

### DETAILED DESCRIPTION

Certain exemplary embodiments provide a basepan assembly for an electrical panel. The basepan assembly can comprise an interconnectable plurality of pieces. In certain exemplary embodiments, a first piece from the plurality of pieces can comprise an inserter. In certain exemplary embodiments, a first piece from the plurality of pieces can comprise a receiver adapted to slidably receive an inserter of a second piece from the plurality of pieces.

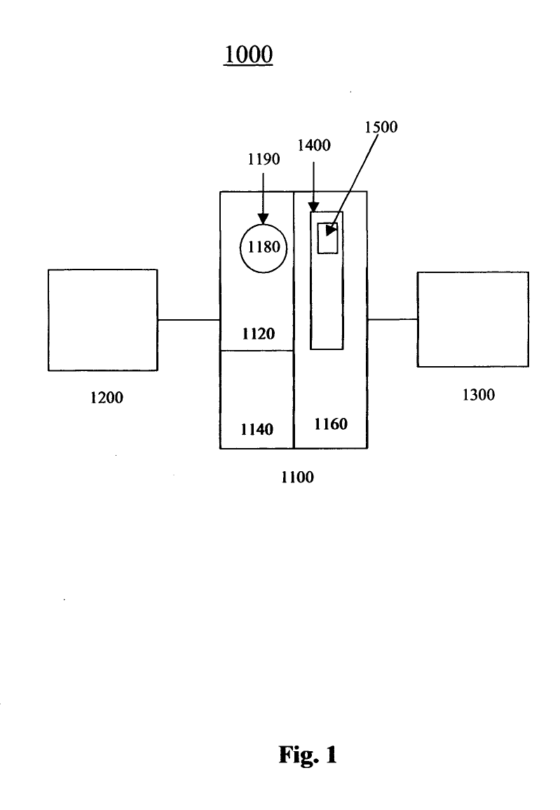

FIG. 1 is a block diagram of an exemplary embodiment of a system 1000, which can comprise an electrical metering panel 1100. Electrical metering panel 1100 can be adapted to measure an electrical parameter associated with electrical power provided by an electrical source 1200 to an electrical load 1300. Via electrical metering panel 1100, electrical source 1200 can be electrically coupled to electrical load 1300. Electrical metering panel 1100 can comprise a meter cover panel 1120 and an electrical meter 1180. Via electrical meter 1180, shielded by a meter cover 1190, a user can observe and/or obtain a value for the electrical parameter. Electrical meter 1180 adapted to be electrically coupled to an electrical sensor associated with a basepan assembly 1400. Electrical metering panel 1100 can comprise a pull cover section 1140. Pull cover section 1140, meter cover panel 1120, and meter cover 1190 can each be adapted to restrict access of the user to electrical wiring and/or devices comprised in electrical metering panel 1100.

System 1000 can be adapted to receive basepan assembly 1400, which can be fixedly and/or releasably attached to electrical panel 1100. Basepan assembly 1400 can be any design and/or architecture of basepan assembly. Basepan assembly 1400 can be electrically coupled to electrical source 1200, via one or more electrical conductors. Basepan assembly 1100 can be adapted to fixedly and/or releasably attach one or more circuit breakers 1500, which can be adapted to electrically couple electrical load 1300 to electrical source 1200.

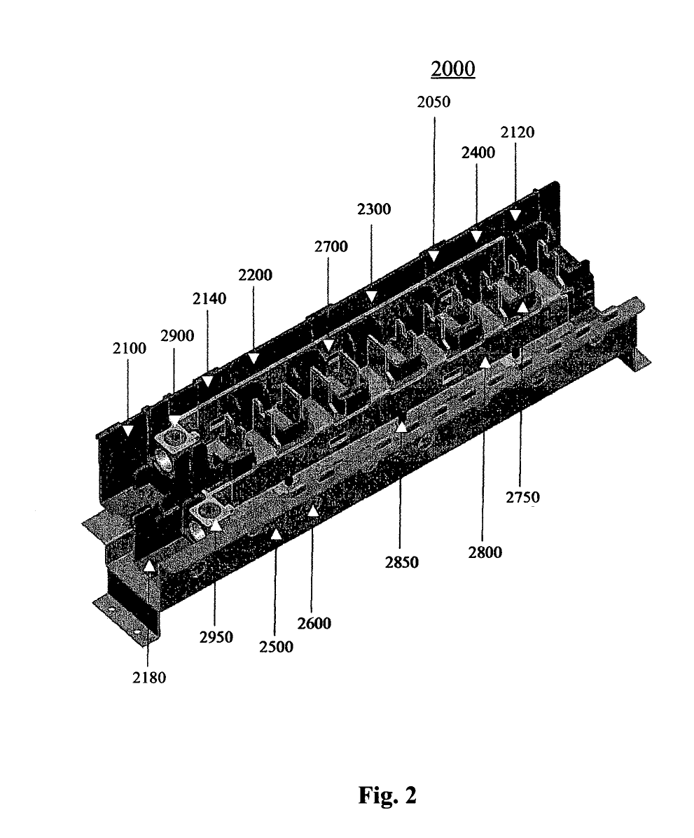

FIG. 2 is a perspective view of an exemplary embodiment of a basepan system 2000, which can comprise a basepan assembly 2050. Basepan assembly 2050 can comprise a first piece 2100, a second piece 2200, a third piece 2300, and/or a fourth piece 2400. First piece 2100, second piece 2200, third piece 2300, and/or fourth piece 2400 can be mechanically, fixedly, releasably, slidably, and/or snapably coupled to form basepan assembly 2050. Basepan assembly 2050 can comprise a thermoplastic substrate 2120 adapted to support one or more of a plurality of bus bars, such as a first bus bar 2700 and/or a second bus bar 2800. First piece 2100 and fourth piece 2400 can be denoted as end pieces. Second piece 2200 and third piece 2300 can be denoted as intermediate pieces. End pieces can be adapted to couple, on only one end of that end piece, to an intermediate piece. Certain end pieces, such as first piece 2100 can be adapted to fixedly and/or releasably attachable to a first lug 2900 and a second lug 2950.

In certain exemplary embodiments, first bus bar 2700 and/or second bus bar 2800 can be snapably attachable to basepan assembly 2050. In certain exemplary embodiments, first bus bar 2700 and second bus bar 2800 can be electrically isolated by a serpentine shaped separation 2750 defined by thermoplastic substrate 2120. In certain exemplary embodiments, first bus bar 2700 and/or second bus bar 2800 can be fixedly and/or releasably attachable to basepan assembly 2050 via one or more fasteners. First bus bar 2700 and/or second bus bar 2800 can be interleaved and/or stacked. In certain exemplary operative embodiments, basepan assembly 2050 can be adapted to:
1. retain a plurality of bus bars, such as first bus bar 2700 and second bus bar 2800, to an electrical panel (not illustrated);
2. mutually align first bus bar 2700 and second bus bar 2800;
3. restrain motion of first bus bar 2700 and second bus bar 2800 in one or more directions parallel to any of three mutually perpendicular axes; and/or
4. mutually electrically insulate first bus bar 2700 and second bus bar 2800.

In certain exemplary basepan assembly 2050 can provide sufficient gutter space for customer wiring, and also allow for a relatively compact load center. A raised configuration can provide sufficient space for running main circuit breaker conductors from a meter side of the electrical panel to a load side beneath basepan assembly 2050. Thus, basepan assembly 2050 can be adapted to provide space for main circuit breaker conductors from a meter side of an electrical panel to a load side of the electrical panel beneath basepan assembly 2050.

In certain exemplary embodiments, basepan assembly 2050 can be adapted to support a plurality of circuit breakers (not illustrated) and can be used for main lug and/or main circuit breaker applications. One or more busbars, such as first bus bar 2700 and/or second bus bar 2800, can be formed, stacked and/or snapped into basepan assembly 2050. First bus bar 2700 and/or second bus bar 2800 can be retained using one or more spring clips on posts 2850 comprised by basepan assembly 2050. Basepan assembly 2050 can comprise a side wall 2140, which can be adapted to receive first bus bar 2700. Basepan assembly 2050 can comprise a bottom portion 2180, which can be adapted to receive second bus bar 2800.

First lug 2900 and second lug 2950, can be used for main lug applications and can be inserted in basepan assembly 2050. Features in basepan assembly 2050 can retain first lug 2900 and second lug 2950. In certain exemplary embodiments, first lug 2900 and second lug 2950 can be adapted to be electrically coupled to corresponding busbars, such as first bus bar 2700 and second bus bar 2800, via one or more fasteners. First lug 2900 and second lug 2950 can be adapted to receive an electrical conductor (not illustrated).

Basepan assembly 2050 can be attachable to a riser bridge 2500, which can be retained along a wall of basepan assembly 2050 to provide conductor routing to a meter side of basepan assembly 2050. Riser bridge 2500 can be used for mounting basepan pieces and/or securing second bus bar 2800. Riser bridge 2500 can be adapted to mount basepan assembly 2050 to the electrical panel. Riser bridge 2500 can be adapted to be retained along a wall of the electrical panel. Riser bridge 2500 can be raised from a wall of the electrical panel associated with basepan assembly 2050 to provide conductor routing to the meter side of the electrical panel. Riser bridge 2500 can be retained along the wall of the electrical panel using one or more fasteners. Certain exemplary embodiments can comprise one or more riser bridge vents 2600 on riser bridge 2500, which can be adapted to channel heat energy away from first bus bar 2700 and second bus bar 2800. Riser bridge vents 2600 can provide for airflow and cooling beneath one or more circuit breakers comprised by basepan assembly 2050.

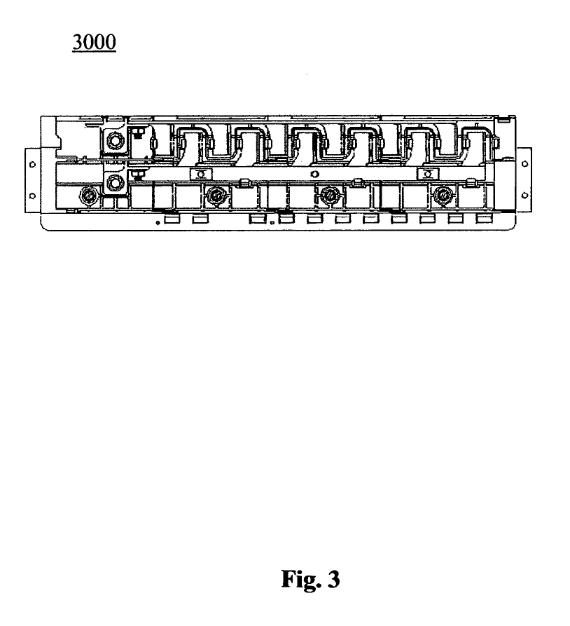

FIG. 3 is a plan view of an exemplary embodiment of a system 3000.

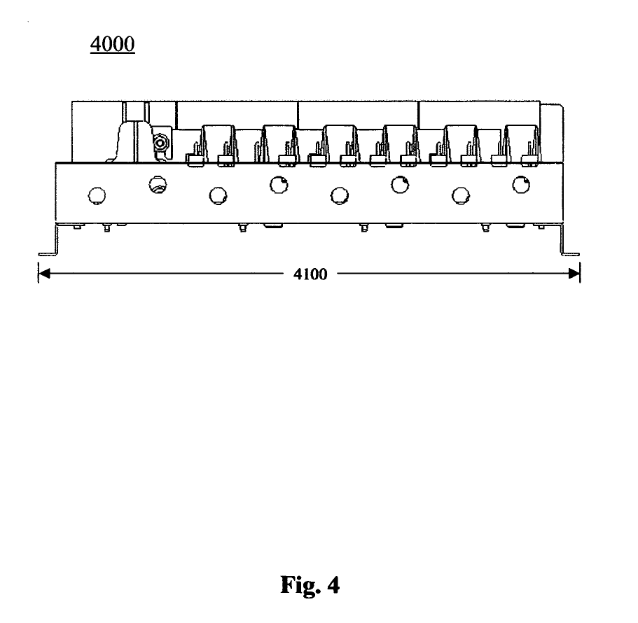

FIG. 4 is a side view of an exemplary embodiment of a system 4000, which can be characterized by a length 4100. In certain exemplary embodiments, length 4100 can be approximately, in inches, 4, 5.9, 8.25, 11.6, 12, 16.875, 17.872, 24, 32.575, 48. 64.5, 90.25, 120, and/or any value or subrange therebetween.

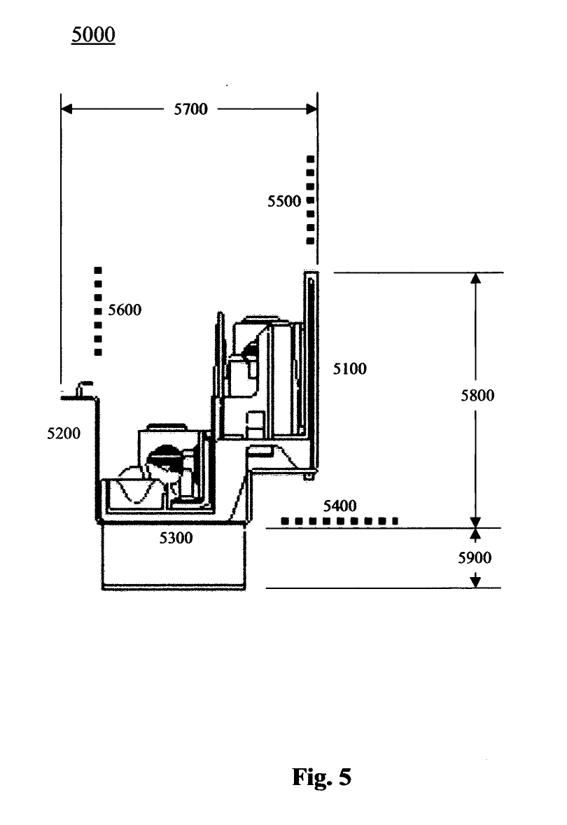

FIG. 5 is an end view of an exemplary embodiment of a system 5000, which can comprise a side wall 5100, a riser bridge 5200, and a bottom portion 5300. Bottom portion 5300 can define a first plane 5400. Side wall 5100 can define a second plane 5500. Second plane 5500 can be approximately perpendicular to first plane 5400. Riser bridge 5200 can define a third plane 5600. Third plane 5600 can be approximately perpendicular to first plane 5400. Each of first plane 5400, second plane 5500 and third plane 5600 are illustrated as being approximately perpendicular to the end view of system 5000 illustrated in FIG. 5.

System 5000 can be characterized by a width 5700, which can be approximately, in inches, 1, 2.7, 4.091, 6.375, 8.275, 12, 16.33, 21.5, 24, 32.65, 36. 62.6, 96, and/or any value or subrange therebetween. System 5000 can be characterized by a depth 5800, which can be approximately, in inches, 1, 2.25, 4.765, 5.157, 6.5, 9.25, 12, 18.66, 20.75, 24, 30.42, 36. 60, and/or any value or subrange therebetween. A flange depth 5900, which can define a separation distance between system 5000 and an electrical panel associated with basepan assembly 5100, can characterize system 5000. Flange depth 5900 can be approximately, in inches, 0.125, 0.375, 0.66, 1, 1.069, 2.875, 4.5, 5.12, 6.75, 8.99, 12, and/or any value or subrange therebetween.

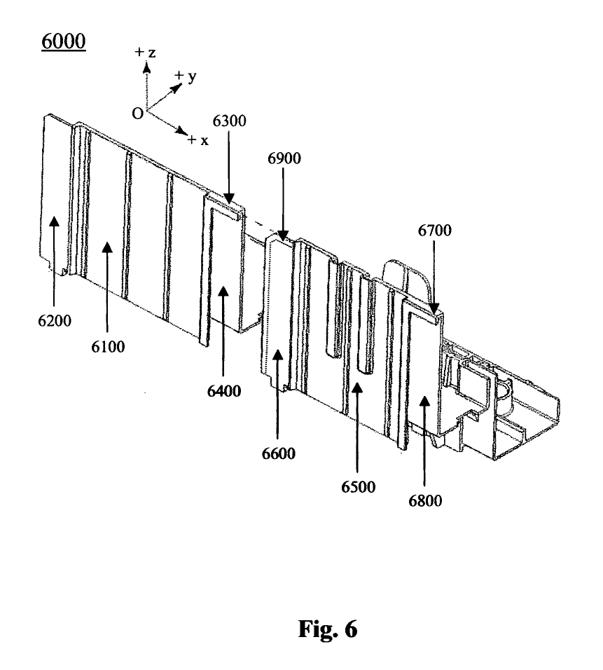

FIG. 6 is a perspective view of an exemplary embodiment of a system 6000, which can comprise a first piece 6100 and a second piece 6500. System 6000 can be utilized to form a basepan assembly for an electrical panel. Piece 6100 and 6500 can be members of a set of interconnectable pieces comprised by the basepan assembly. First piece 6100 and second piece 6500 can be interleaved and/or snapably coupled together for retention. In certain exemplary embodiments, pieces used to form system 6000 can be re-used and/or coupled to each other. In certain exemplary embodiments, piece 6100 and/or piece 6500 can comprise one or more snapable attachments, such as a springable clip.

First piece 6100 can comprise an inserter 6200. First piece 6100 can comprise a receiver 6400 adapted to slidably receive an inserter 6600 of second piece 6500. When receiver 6400 and inserter 6600 are mechanically coupled, for each of three mutually perpendicular axes x, y, and z; second piece 6500 can be releasably restrained from moving relative to first piece 6100 in at least one direction parallel to the axis.

Receiver 6400 can comprise a flange 6300, which can be adapted to releasably engage with an edge 6900 of inserter 6600. When engaged with inserter 6600, flange 6300 can be adapted to restrain second piece 6500 from moving relative to first piece 6100 in, for example, a negative x direction and a positive z direction with first piece 6100 and second piece 6500 oriented as illustrated in FIG. 6. When engaged with inserter 6600, receiver 6400 can be adapted to restrain second piece 6500 from moving relative to first piece 6100 in a negative y direction and a positive y direction with first piece 6100 and second piece 6500 oriented as illustrated in FIG. 6.

Second piece 6500 can comprise a receiver 6800, which can comprise a flange 6700. Receiver 6800 and flange 6700 can be adapted to receive an inserter from a third piece (not illustrated).

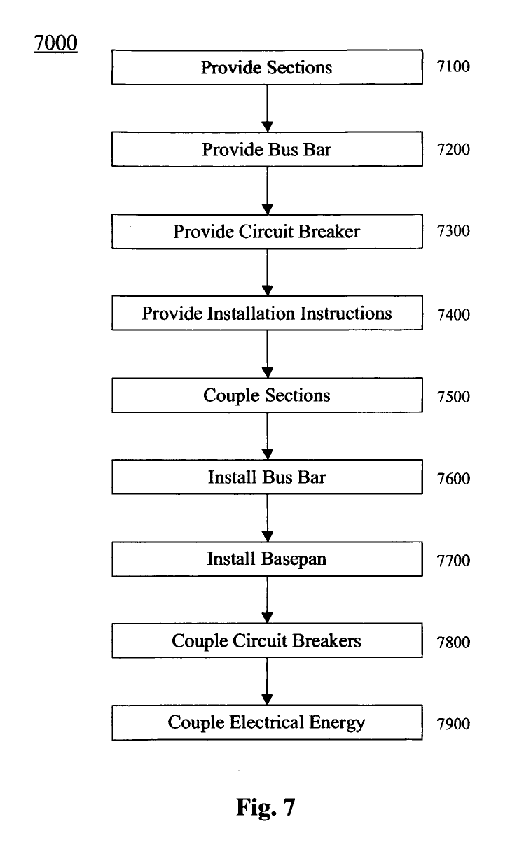

FIG. 7 is a flowchart of an exemplary embodiment of a method 7000. At activity 7100, an interconnectable plurality of pieces of a basepan assembly can be provided and/or obtained. A first piece from the plurality of pieces can comprise an inserter and a receiver. The receiver can be adapted to slidably receive an inserter of a second piece from the plurality of pieces. The receiver can be adapted to, for each of three mutually perpendicular axes, releasably restrain the second piece from moving relative to the first piece in at least one direction parallel to the axis.

At activity 7200, one or more bus bars can be provided and/or obtained. The basepan assembly can be configured to releasably, clipably, and/or snapably couple the one or more bus bars to the basepan assembly.

At activity 7300, one or more circuit breakers can be provided and/or obtained. The circuit breakers can be designed to be releasably and/or pluggably attached to the basepan assembly.

At activity 7400, installation instructions related to the basepan assembly can be provided and/or obtained. The installation instructions can provide information to an assembler and/or user of the basepan assembly regarding one or more of coupling the pieces, installing the bus bars, installing lugs, installing conductors, installing the basepan assembly in an electrical panel, electrically coupling circuit breakers to the basepan assembly, wiring the circuit breakers, and/or connecting an electrical energy source to the electrical panel, etc.

At activity 7500, two or more of the plurality of pieces can be coupled to form the basepan assembly. In certain exemplary embodiments, the plurality of pieces can be fixedly, slidably, snapably, and/or releasably coupled.

At activity 7600, the one or more bus bars can be mechanically coupled to the basepan assembly. In certain exemplary embodiments, the bus bars can be snapably attached to the basepan assembly. In certain exemplary embodiments, the bus bars can be adapted to slide over one or more posts. Each of the posts can be adapted to fixedly and/or releasably attach the bus bar to the basepan assembly via one or more clips. In an operative embodiment, the basepan assembly can be adapted to retain a plurality of bus bars to the electrical panel; mutually align the plurality of bus bars; restrain motion of the plurality of bus bars in the one or more directions parallel to any of the three mutually perpendicular axes; and/or mutually electrically isolate the plurality of bus bars.

At activity 7700, the basepan assembly can be installed in an electrical panel, such as via one or more fasteners.

At activity 7800, one or more circuit breakers can be mechanically and/or electrically coupled to the basepan assembly.

At activity 7900, a source of electrical energy can be electrically coupled to the basepan assembly.

### Note

Still other practical and useful embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of this application.

Thus, regardless of the content of any portion (e.g., title, field, background, summary, abstract, drawing figure, etc.) of this application, unless clearly specified to the contrary, such as via an explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
any elements can be integrated, segregated, and/or duplicated;
any activity can be repeated, performed by multiple entities, and/or performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such incorporated by reference material is specifically not incorporated by reference herein.

Accordingly, the descriptions and drawings are to be regarded as illustrative in nature, and not as restrictive.

What is claimed is:

1. A system comprising:
a basepan assembly for an electrical panel, said basepan assembly comprising an interconnectable plurality of pieces, a first piece from said plurality of pieces comprising:
an inserter; and
a receiver adapted to slidably receive an inserter of a second piece from said plurality of pieces and, for each of three mutually perpendicular axes, to releasably restrain said second piece from moving relative to said first piece in at least one direction parallel to said axis;
in an operative embodiment, said basepan assembly adapted to:
retain a plurality of bus bars to said electrical panel;
mutually align said plurality of bus bars;
restrain motion of said plurality of bus bars in said one or more directions parallel to any of said three mutually perpendicular axes; and
mutually electrically insulate said plurality of bus bars.

2. The system of claim 1, further comprising:
a bus bar of said plurality of bus bars.

3. The system of claim 1, further comprising:
a bus bar of said plurality of bus bars, said bus bar adapted to be snapably attachable to said basepan assembly.

4. The system of claim 1, further comprising:
one or more electrical circuit breakers adapted to be releasably attachable to said basepan assembly.

5. The system of claim 1, further comprising:
an electrical panel adapted to receive said basepan assembly.

6. The system of claim 1, further comprising:
an electrical panel adapted to receive said basepan assembly; and
an electrical meter adapted to electrically couple to an electrical sensor associated with said basepan assembly.

7. The system of claim 1, further comprising:
a lug adapted to be coupled to a bus bar of said plurality of bus bars, said lug adapted to receive an electrical conductor.

8. The system of claim 1, wherein said basepan assembly comprises a bottom portion adapted to receive a bus bar of said plurality of bus bars.

9. The system of claim 1, wherein said basepan assembly comprises a side wall adapted to receive a bus bar of said plurality of bus bars.

10. The system of claim 1, wherein said basepan assembly comprises a riser bridge comprising a plurality of riser bridge vents.

11. The system of claim 1, wherein said basepan assembly comprises a riser bridge comprising a plurality of riser bridge vents, said plurality of riser bridge vents adapted to channel heat energy away from a bus bar of said plurality of bus bars.

12. The system of claim 1, wherein said basepan assembly comprises:
a bottom portion adapted to receive a first bus bar of said plurality of bus bars, said bottom portion defining a first plane;
a side wall adapted to receive a second bus bar of said plurality of bus bars, said side wall defining a second plane, said second plane approximately perpendicular to said first plane; and
a riser bridge comprising a plurality of riser bridge vents, said riser bridge defining a third plane, said third plane approximately perpendicular to said first plane, said plurality of riser bridge vents adapted to channel heat energy away from at least said first bus bar of said plurality of bus bars.

13. The system of claim 1, further comprising:
a riser bridge is adapted to mount said basepan assembly to said electrical panel.

14. The system of claim 1, further comprising:
a riser bridge adapted to provide conductor routing to a meter side of said basepan assembly.

15. The system of claim 1, further comprising:
a riser bridge adapted to be retained along a wall of an electrical panel.

16. The system of claim 1, wherein said basepan assembly is adapted to provide space for main circuit breaker conductors from a meter side of an electrical panel to a load side of said electrical panel beneath said basepan assembly.

17. The system of claim 1, wherein said basepan assembly comprises a thermoplastic substrate adapted to support one or more of said plurality of bus bars.

18. The system of claim 1, wherein said basepan assembly comprises a thermoplastic substrate adapted to support a fast bus bar and a second bus bar of said plurality of bus bars, said first bus bar and said second bus bar electrically isolated by a serpentine shaped separation defined by said thermoplastic substrate.

19. A method comprising:
installing a basepan device, comprising an interconnectable plurality of pieces, a first piece from said plurality of pieces comprising:
an inserter; and
a receiver adapted to slidably receive an inserter of a second piece from said plurality of pieces and, for each of three mutually perpendicular axes, to releasably restrain said second piece from moving relative to said first piece in at least one direction parallel to said axis;
in an operative embodiment, said basepan assembly adapted to:
retain a plurality of bus bars to said electrical panel;
mutually align said plurality of bus bars;
restrain motion of said plurality of bus bars in said one or more directions parallel to any of said three mutually perpendicular axes; and
mutually electrically isolate said plurality of bus bars.

20. A basepan device comprising:
a plurality of coupled pieces, each piece comprising:
an inserter; and
a receiver adapted to slidably receive an inserter of a second piece from said plurality of pieces and, for each of three mutually perpendicular axes, to releasably restrain said second piece from moving relative to said first piece in at least one direction parallel to said axis.
